(19) United States
(12) Patent Application Publication
(10) Pub. No.: US 2006/0102079 A1
(43) Pub. Date: May 18, 2006

(54) Reducing variability in delivery rates of solid state precursors

(76) Inventors: Timothy E. Glassman, Portland, OR (US); Larry J. Foley, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/989,984

(22) Filed: Nov. 15, 2004

(51) Int. Cl. C23C 16/00; B29C 51/08

(52) U.S. Cl. 118/726; 264/322

(57) ABSTRACT

An apparatus comprises a chemical precursor material formed into a pellet-shaped structure. The chemical precursor pellet may be used in a chemical vapor deposition process or in an atomic layer deposition process. A method of making the chemical precursor pellets comprises introducing the chemical precursor material into a pellet-shaped mold, compressing the chemical precursor material within the mold into a chemical precursor pellet, and removing the chemical precursor pellet from the mold. Another method for making the chemical precursor pellets comprises introducing a chemical precursor material into a pellet-shaped mold, liquefying at least a portion of the chemical precursor material within the mold, solidifying the liquefied chemical precursor material within the mold to form a chemical precursor pellet, and removing the chemical precursor pellet from the mold.

### TECHNICAL FIELD OF THE INVENTION

The invention generally relates to deposition processes, namely, methods and apparatus to reduce variability in delivery rates of solid state precursors.

### BACKGROUND

Deposition systems, such as atomic layer deposition (ALD) systems or chemical vapor deposition (CVD) systems, are used to apply deposition materials to a substrate. The deposition materials generally begin as one or more solid chemical precursors that are often in a powder or other granular form. The chemical precursors are heated to temperatures at which they will vaporize, and the resulting vapors react at the surface of the substrate to create a deposition film.

One of the problems in conventional ALD and CVD systems has been the difficulty in maintaining consistent concentrations of the chemical precursors as they are delivered in the vapor phase. The delivery of repeatable concentrations of chemical precursors has been addressed in numerous fashions. Some delivery systems require major hardware changes for existing deposition tools and the use of unproven manufacturing technologies.

One common solution for vapor delivery is use of a cylinder that is filled with the desired solid precursor and heated until the desired concentration of precursor is reached in the vapor phase. In this process, the temperature must be adjusted periodically based on thickness or uniformity changes in the resultant deposition film. If the precursor concentration or the resulting film properties are not frequently monitored, incomplete deposition on the substrate may occur resulting in a loss of product. Frequent and careful monitoring adds additional costs to the process and reduces the availability of production tools. If the precursor concentrations must be changed, the process becomes even more difficult to control.

Another complication encountered in the use of solid chemical precursor sources for vapor phase delivery is the changing vaporization rate of the solid precursor as the material ages. This aging effect, which can become worse due to operating at high temperatures, results in changes to the surface area of the material, crystallinity, solid packing (all summarized as sintering) and carrier gas flow path. This causes the delivery rate to become unstable during the initial phase of delivery and decreases with time. This instability and reduction in precursor concentration can lead to varying film uniformity and composition. Ultimately, these problems can lead to depletion of deposition coverage on the substrate.

### BRIEF DESCRIPTION OF THE DRAWINGS

FIG. 1 illustrates a chemical tank with a chemical precursor material in a powder or granular form.

FIG. 2A is a method for forming chemical precursor pellets in accordance with an implementation of the invention.

FIG. 2B is a reflow process for forming chemical precursor pellets in accordance with an implementation of the invention.

FIG. 2C is an alternate reflow process for forming chemical precursor pellets in accordance with an implementation of the invention.

FIGS. 3A to 3D illustrate various pellet shapes in accordance with implementations of the invention.

FIG. 4 illustrates a chemical tank with solid precursor pellets in accordance with an implementation of the invention.

FIG. 5 illustrates a chemical tank with wire mesh sieves in accordance with an implementation of the invention.

### DETAILED DESCRIPTION

In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

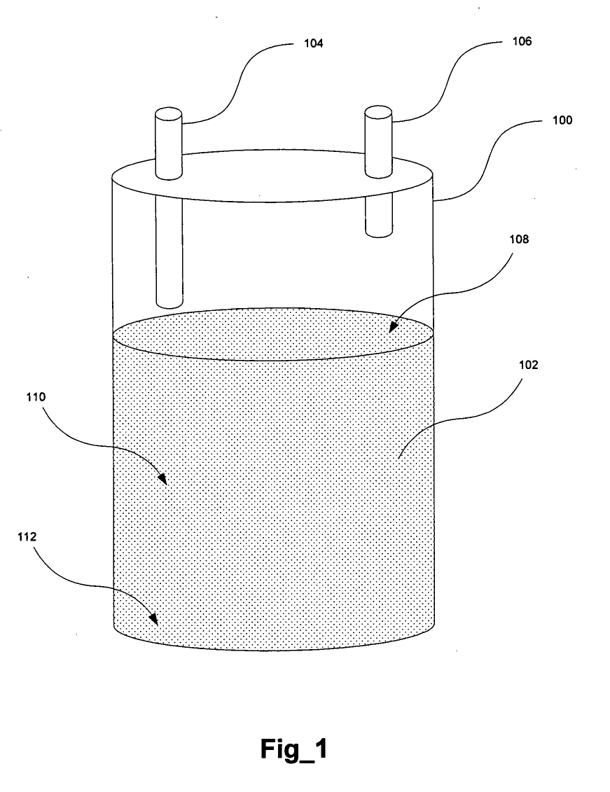

FIG. 1 illustrates one of the problems with known deposition systems where solid chemical precursors begin as a densely packed powder or another granular form. FIG. 1 includes a delivery tank 100 that stores and delivers a chemical precursor 102. The delivery tank 100 may include an inlet 104 and an outlet 106. The inlet 104 may be used to introduce a flowing carrier gas into the delivery tank 100. The outlet 106 may provide an exit path for the flowing carrier gas and the chemical precursor 102 when the precursor 102 is heated into a vapor to be delivered to a deposition chamber. Examples of such deposition chambers include, but are not limited to, a chemical vapor deposition (CVD) chamber or an atomic layer deposition (ALD) chamber.

In known systems, when the chemical precursor 102 is heated, it is generally a top surface 108 of the chemical precursor 102 that vaporizes. Because the chemical precursor powder is densely packed, the chemical precursor in the middle of the tank 100 (e.g., chemical precursor 110) or towards the bottom of the tank 100 (e.g., chemical precursor 112) is heated but does not vaporize. The chemical precursor in the middle and at the bottom of the tank 100 undergoes a continual heating that causes this precursor material to suffer from aging and degradation effects. Over time, when the level of the chemical precursor 102 drops and the precursor material in the middle or at the bottom of the tank is finally used, the aging and degradation effects may alter the concentration and flow rate of the chemical precursor vapor. In addition, the concentration and flow rate of the chemical precursor vapor in the middle will be different than the concentration and flow rate of the chemical precursor vapor at the bottom since the chemical precursor at the bottom will endure the heating for a longer period of time. This will cause the precursor vapor delivery rate to become unstable and the delivery rate may decrease with time. As noted above, the instability and reduction in precursor concentration can lead to varying film uniformity and composition, and ultimately to depletion of deposition coverage on the substrate. Continual monitoring of the precursor concentration adds additional costs to the process and makes the process more difficult to control.

Implementations of the invention may be used to improve the delivery rate of solid chemical precursors for thin film deposition processes. The invention may be used for many types of chemical precursors used in thin film deposition processes. For instance, in ALD and CVD systems, implementations of the invention may be used with solid chemical precursors such as main group and transition metal halides, alkoxides, amides, alkyls, hydrides, diketonates, carbonyls, and a range of other metal organic compounds, complexes, and ligands. In some implementations, ruthenium based chemicals may be used. In other implementations of the invention, solid chemical precursors not described herein may be used.

In accordance with implementations of the invention, the chemical precursor may be formed into pellets prior to being used in a deposition process. In some implementations, the chemical precursor may be formed into pellets by a manufacturer of chemical precursors. In some implementations, the chemical precursor may be formed into pellets prior to being placed into the delivery tank 100.

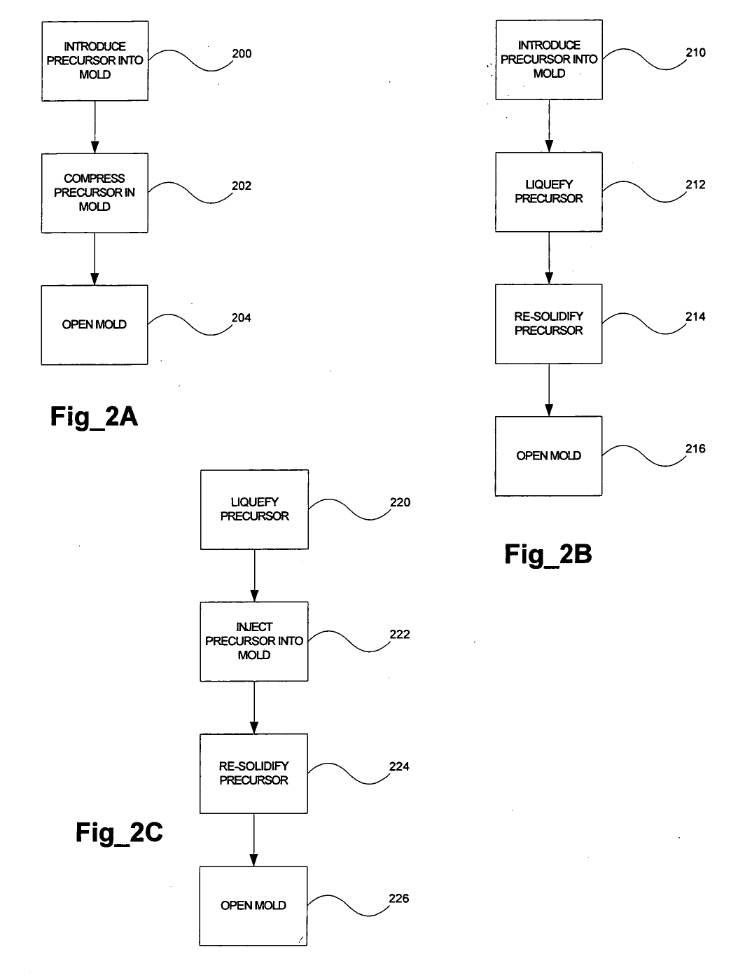

FIG. 2A describes one implementation of a method for forming pellets of chemical precursor material. A predetermined amount of the chemical precursor, while still in powder form, may be introduced into a pellet-shaped mold (200). In some implementations, a binder material may be included with the chemical precursor powder to improve the adhesion properties of the powder. The binder material may be in a solid powder or a liquid form. Pressure may be exerted by the mold on the chemical precursor powder to compress the powder together (202). The pressure exerted on the chemical precursor powder may be sufficient to cause the powder to adhere together and form a pellet. The mold may then be opened and the compressed pellet of chemical precursor may be removed (204). In some implementations, molds may be used that process multiple pellets per batch.

FIG. 2B illustrates a reflow process to convert the chemical precursor powder into pellets in accordance with an implementation of the invention. The chemical precursor powder may be introduced into a pellet-shaped mold (210). The temperature of the chemical precursor powder may then be elevated to cause the chemical precursor powder to partially or completely liquefy within the mold (212). Once liquefied, the temperature of the chemical precursor may then be reduced to cause the precursor to re-solidify into a pellet rather than a powder (214). The mold may then be opened and the solid pellet of chemical precursor may be removed (216).

FIG. 2C is another implementation of a reflow process. Here, the chemical precursor powder may be partially or completely liquefied prior to being injected into the mold (220). In some implementations, the temperature of the precursor may be elevated to cause the precursor to liquefy. In other implementations, the pressure exerted on the precursor may be reduced to cause the precursor to liquefy. The liquefied precursor is then injected into the mold (222). The temperature or pressure on the chemical precursor may then be adjusted to cause the chemical precursor to re-solidify within the mold as a pellet (224). The mold may then be opened and the solid pellet of chemical precursor may be removed (226). In some implementations, the reflow process may eliminate the need for a binder material.

In some implementations, the manufacturing process for the chemical precursor may be altered to generate the chemical precursor in pellet form rather than powder form. In some implementations, this may be carried out using known methods for creating compressed structures from powders, for example, methods used by the pharmaceutical industry to create pills and tablets from powdered medication. In some implementations, the manufacturing process may include mixing the chemical precursor powder with binders and compressing the mixture into pellet form. In other implementations, the chemical precursor may be manufactured as a liquid that may be solidified downstream into pellets.

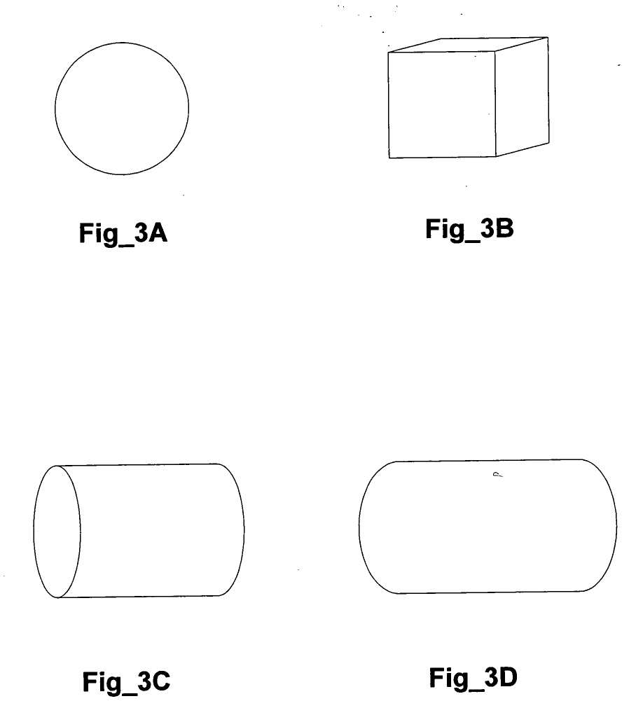

FIGS. 3A to 3D illustrate some implementations of pellets 300 that may be used in accordance with the invention. As shown, the pellets may be spherical (FIG. 3A), cubic or rectangular (FIG. 3B), cylindrical (FIG. 3C), or elliptical (FIG. 3D). It should be noted that the shape of the pellets 300 is not limited to those shown in FIGS. 3A to 3D. In some implementations, three-dimensional structures other than those shown here may be used, including but not limited to shapes used by known lozenges or tablets. In some implementations, random shapes may be used to form the pellets. In other implementations, combinations of one or more of the above described shapes may be used. In some implementations, the pellets 300 may be sized such that when they are introduced into the delivery tank 100, sufficient void space is left between pellets 300 to allow a carrier gas to flow through the void spaces with minimal disturbance to the pellets 300. This reduces the likelihood that the pellets 300 may excessively rub together and generate small particle debris.

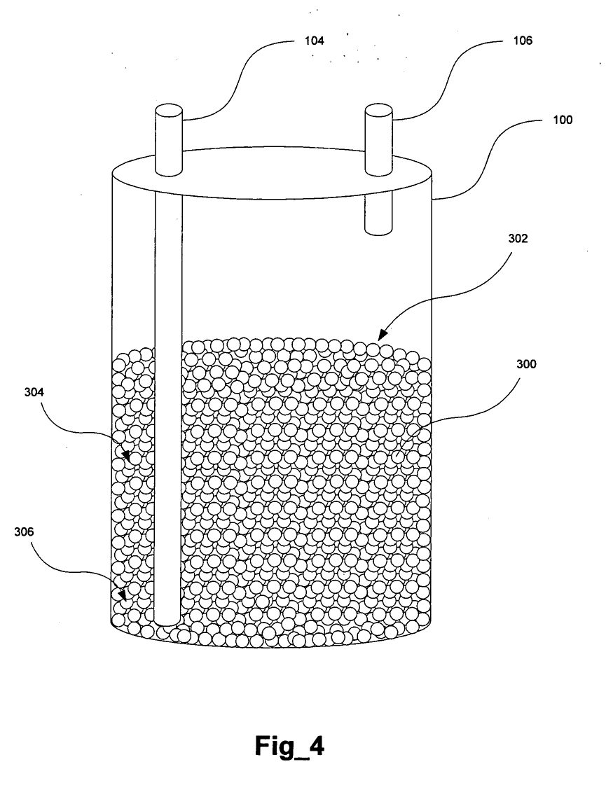

FIG. 4 illustrates an implementation of the invention in which the chemical precursor pellets 300 are loaded into the delivery tank 100. Unlike the chemical precursor 102 in powder form, the shape of the chemical precursor pellets 300 prevents them from becoming densely packed. As shown, when the chemical precursor pellets 300 are loaded into the delivery tank 100, their shape creates void spaces between adjacent pellets 300. These void spaces increase the volume of the chemical precursor pellets 300 relative to a powder and therefore decrease its density. These void spaces also create channels throughout the entire volume of chemical precursor pellets 300 in the tank 100.

When the chemical precursor pellets 300 are heated for use in a deposition process, the void spaces and channels provide room for the pellets 300 in the middle 304 and at the bottom 306 of the tank 100 to vaporize. Unlike the chemical precursor powder 102 where only the top surface 108 is vaporized, as shown in FIG. 1, the invention enables the entire volume of the chemical precursor pellets 300 to be used to generate chemical precursor vapor. This reduces the effects of aging and degradation that occur in known processes where the precursor in the middle and at the bottom of the tank is heated but does not vaporize. The reduced effects of aging and degradation aid in stabilizing the vaporization rate of the pellets 300.

In some implementations, a carrier gas may be introduced at the bottom of the tank 100 by the inlet 104, as shown in FIG. 4. The carrier gas may travel up through the void spaces and channels of the chemical precursor pellets 300 to pick up or displace chemical precursor vapor. The carrier gas therefore picks up vapor throughout the volume of the chemical vapor pellets 300 and not just off of the top surface 302 of the pellets 300. This may further aid in reducing the effects of aging and degradation by yielding a more uniform aging of the chemical precursor and a more predictable concentration delivered over time. The void spaces and channels also provide more efficient carrier gas flow throughout the chemical precursor, allowing for more rapid and efficient vapor replenishment.

In addition, the void spaces and channels in the volume of the chemical precursor pellets 300 may expose a substantially consistent surface area to the carrier gas. This substantially consistent surface area may further aid in stabilizing the vaporization rate of the chemical precursor pellets 300 and therefore provides a more consistent chemical precursor concentration in the vapor. In some implementations, the substantially consistent surface area may also enable delivery of higher concentrations of chemical precursor at the same temperature or may enable transport of thermally unstable materials at the same concentration by lowering the delivery temperature.

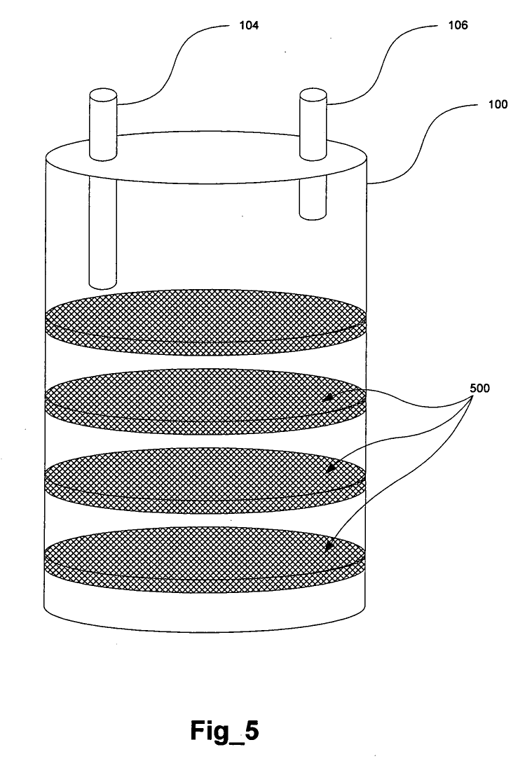

FIG. 5 illustrates another implementation of the invention where one or more wire mesh sieves 500 are used to hold the pellets 300 (not shown in FIG. 5). The wire mesh sieves 500 provide additional support and separation for the pellets 300 to further ensure consistent delivery in accordance with the invention. The wire mesh sieves 500 enable carrier gas flow to occur without solid compaction of the pellets 300. In other implementations, an alternate infrastructure or matrix may be used to provide support for the pellets 300 without hindering carrier gas flow.

The implementations of the invention described herein provide improved solid source delivery for deposition systems such as ALD systems and CVD systems. Implementations of the invention provide more uniform delivery of precursor vapor concentration and improved vaporization rate by reducing the batch-to-batch variability of particle size, surface area, and powder packing in the delivery tank 100 to more consistent values.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
introducing a chemical precursor material into a pellet-shaped mold;
compressing the chemical precursor material within the mold into a chemical precursor pellet; and
removing the chemical precursor pellet from the mold.

2. The method of claim 1, wherein the pellet-shaped mold comprises a spherical shape, an elliptical shape, a cubic shape, a rectangular shape, a cylindrical shape, or a tablet shape.

3. The method of claim 1, wherein the chemical precursor material comprises a material from the group consisting of main group and transition metal halides, alkoxides, amides, alkyls, hydrides, diketonates, and carbonyls.

4. The method of claim 1, wherein the chemical precursor material comprises a material from the group consisting of metal organic compounds, metal organic complexes, and metal organic ligands.

5. The method of claim 1, wherein the chemical precursor pellet may be used in a chemical vapor deposition process or an atomic layer deposition process.

6. A method comprising:
introducing a chemical precursor material into a pellet-shaped mold;
liquefying at least a portion of the chemical precursor material within the mold;
solidifying the liquefied chemical precursor material within the mold to form a chemical precursor pellet; and
removing the chemical precursor pellet from the mold.

7. The method of claim 6, wherein the pellet-shaped mold comprises a spherical shape, an elliptical shape, a cubic shape, a rectangular shape, a cylindrical shape, or a tablet shape.

8. The method of claim 6, wherein the chemical precursor material comprises a material from the group consisting of main group and transition metal halides, alkoxides, amides, alkyls, hydrides, diketonates, and carbonyls.

9. The method of claim 6, wherein the chemical precursor material comprises a material from the group consisting of metal organic compounds, metal organic complexes, and metal organic ligands.

10. The method of claim 6, wherein the liquefying comprises heating at least a portion of the chemical precursor material to cause the material to melt.

11. The method of claim 10, wherein the chemical precursor material is indirectly heated by heating the mold.

12. The method of claim 6, wherein the solidifying comprises cooling at least a portion of the liquefied chemical precursor material to cause the material to solidify.

13. The method of claim 12, wherein the chemical precursor material is indirectly cooled by cooling the mold.

14. The method of claim 6, wherein the chemical precursor pellet may be used in a chemical vapor deposition process or an atomic layer deposition process.

15. A method comprising:
liquefying at least a portion of a chemical precursor material;
injecting the chemical precursor material into a pellet-shaped mold;
solidifying the liquefied chemical precursor material within the mold to form a chemical precursor pellet; and
removing the chemical precursor pellet from the mold.

16. The method of claim 15, wherein the chemical precursor material comprises a material from the group consisting of main group and transition metal halides, alkoxides, amides, alkyls, hydrides, diketonates, and carbonyls.

17. The method of claim 15, wherein the chemical precursor material comprises a material from the group consisting of metal organic compounds, metal organic complexes, and metal organic ligands.

18. The method of claim 15, wherein the liquefying comprises heating at least a portion of the chemical precursor material to cause the material to melt.

19. The method of claim 15, wherein the liquefying comprises reducing the pressure exerted on at least a portion of the chemical precursor material to cause the material to melt.

20. The method of claim 15, wherein the solidifying comprises cooling at least a portion of the liquefied chemical precursor material to cause the material to solidify.

21. The method of claim 15, wherein the solidifying comprises increasing a pressure exerted on at least a portion of the liquefied chemical precursor material to cause the material to solidify.

22. The method of claim 15, wherein the chemical precursor pellet may be used in a chemical vapor deposition process or an atomic layer deposition process.

23. An apparatus comprising
a chemical precursor powder that has been molded into a pellet-shaped structure; and
a binder material to improve the adhesion properties of the powder.

24. The apparatus of claim 23, wherein the pellet-shaped structure comprises an elliptical shape, a cubic shape, a rectangular shape, a cylindrical shape, or a tablet shape.

25. The apparatus of claim 23, wherein the pellet-shaped structure may be used in a chemical vapor deposition process or an atomic layer deposition process.

26. (canceled)

27. (canceled)

28. (canceled)

29. The apparatus of claim 23, wherein the chemical precursor powder has been molded by compressing the chemical precursor powder and the binder material within a mold.

30. The apparatus of claim 23, wherein the chemical precursor powder has been molded by using a reflow process.

31. The apparatus of claim 23, wherein the chemical precursor powder comprises at least one of a metal halide, a metal alkoxide, a metal amide, a metal alkyl, a metal hydride, or a metal diketonate.
